(19) United States
(12) Patent Application Publication
(10) Pub. No.: US 2025/0200881 A1
(43) Pub. Date: Jun. 19, 2025

(54) COLLISION MANAGEMENT IN EXTENDED REALITY SCENE DESCRIPTION

(71) Applicant: InterDigital CE Patent Holdings, SAS, Paris (FR)

(72) Inventors: Patrice Hirtzlin, Betton (FR); Pierrick Jouet, Rennes (FR); Sylvain Lelievre, Montgermont (FR); Loic Fontaine, noyal sur vilaine (FR); Etienne Faivre d'Arcier, Saint Gonlay (FR)

(21) Appl. No.: 18/846,895

(22) PCT Filed: Mar. 6, 2023
(86) PCT No.: PCT/EP2023/055588

§ 371 Date: Sep. 13, 2024

(30) Foreign Application Priority Data
Mar. 14, 2022 (EP) 22305289.5

(51) Int. Cl. G06T 17/00; G06T 17/20; G06T 19/00

(52) U.S. Cl. CPC G06T 17/005; G06T 17/20; G06T 19/006; G06T 2210/21; G06T 2210/61

(57) ABSTRACT

Methods, device and data stream are provided to initiate an extended reality application that uses a physics engine. The scene description comprises behavior data based on triggers. At least one trigger is a collision trigger that is activated in case of a collision between two objects described in nodes of the scene graph of the scene description. The scene description comprises, at the node level, a description of how the object of a given node has to be considered by the physics engine in order to optimize the use of memory and processing resources. A node is of one of three categories: to be ignored by the physics engine, to be considered only for collision or to be considered for a full physics simulation. At the starting, the physics engine is initialized according to these categories and the extended reality application is started in the best conditions.

### 1. TECHNICAL FIELD

The present principles generally relate to the domain of extended reality scene description and extended reality scene rendering. In particular, the present principles relate to the description of the management of collisions between objects of the scene. The present document is also understood in the context of the formatting and the playing of extended reality applications when rendered on end-user devices such as mobile devices or Head-Mounted Displays (HMD).

### 2. BACKGROUND

The present section is intended to introduce the reader to various aspects of art, which may be related to various aspects of the present principles that are described and/or claimed below. This discussion is believed to be helpful in providing the reader with background information to facilitate a better understanding of the various aspects of the present principles. Accordingly, it should be understood that these statements are to be read in this light, and not as admissions of prior art.

Extended reality (XR) is a technology enabling interactive experiences where the real-world environment and/or a video content is enhanced by virtual content, which can be defined across multiple sensory modalities, including visual, auditory, haptic, etc. During runtime of the application, the virtual content (3D content or audio/video file for example) is rendered in real-time in a way that is consistent with the user context (environment, point of view, device, etc.). Scene graphs (such as the one proposed by Khronos/glTF and its extensions defined in MPEG Scene Description format or Apple/USDZ for instance) are a possible way to represent the content to be rendered. They combine a declarative description of the scene structure linking real-environment objects and virtual objects on one hand, and binary representations of the virtual content on the other hand. Scene description frameworks ensure that the timed media and the corresponding relevant virtual content are available at any time during the rendering of the application. Scene descriptions can also carry data at scene level describing of how the scene objects interact at runtime for immersive XR experiences. The management of collisions between objects (real and/or virtual, a user being a real object) requires the use of a physic engine that is memory and processing resources expansive. In existing XR scene description formats, there is a lack of mechanisms that takes advantage of the different kinds of collision behaviors for the management of memory and processing resources.

### 3. SUMMARY

The following presents a simplified summary of the present principles to provide a basic understanding of some aspects of the present principles. This summary is not an extensive overview of the present principles. It is not intended to identify key or critical elements of the present principles. The following summary merely presents some aspects of the present principles in a simplified form as a prelude to the more detailed description provided below.

The present principles relate to a method of initiating an extended reality application that uses a physics engine. The method comprises the step of obtaining a description of an extended reality scene. The description comprises a scene graph and at least two nodes of the scene graph comprise a collision information according to the present principles. The scene graph comprises at least two such nodes, because a collision occurs between at least two objects describes in such nodes. The collision information comprises a first Boolean value indicating whether an object described in the node is static, a mesh information and a second Boolean value indicating whether physics of the object described in the node is simulated and, on condition that the second Boolean value is true, physics body parameters and material information. Then, the method comprises, for nodes of the scene graph comprising a collision information, initializing the physics engine for collision detection with the first Boolean value and the mesh information. On condition that the second Boolean value is true, the method further comprises the step of initializing the physics engine for physics simulation with the physics body parameters and the material information. When the physics engine is initialized with a configuration and parameters that allow to save memory and processing resources, the extended reality application is initiated.

The present principles also relate to an extended reality rendering device comprising a memory associated with a processor configured to implement the method above.

The present principles also relate to a data stream carrying data representative of a description of an extended reality scene. The description comprises:
a scene graph linking nodes;
at least two nodes of the scene graph comprising a collision information, the collision information comprising:
   a first Boolean value indicating whether an object described in the node is static, a mesh information and a second Boolean value indicating whether physics of the object described in the node is simulated; and
   on condition that the second Boolean value is true, physics body parameters and material information.

### 4. BRIEF DESCRIPTION OF DRAWINGS

The present disclosure will be better understood, and other specific features and advantages will emerge upon reading the following description, the description making reference to the annexed drawings wherein:

FIG. 1 shows an example graph of an extended reality scene description according to the present principles;

FIG. 2 shows a non-limitative example of an extended reality scene comprising real and virtual objects;

FIG. 3 shows an example architecture of an XR processing engine which may be configured to implement a method described in relation with FIG. 5 according to the present principles;

FIG. 4 shows an example of an embodiment of the syntax of a data stream encoding an extended reality scene description according to the present principles;

FIG. 5 illustrates a method for initiating an extended reality application comprising collision events according to the present principles.

### 5. DETAILED DESCRIPTION OF EMBODIMENTS

The present principles will be described more fully hereinafter with reference to the accompanying figures, in which examples of the present principles are shown. The present principles may, however, be embodied in many alternate forms and should not be construed as limited to the examples set forth herein. Accordingly, while the present principles are susceptible to various modifications and alternative forms, specific examples thereof are shown by way of examples in the drawings and will herein be described in detail. It should be understood, however, that there is no intent to limit the present principles to the particular forms disclosed, but on the contrary, the disclosure is to cover all modifications, equivalents, and alternatives falling within the spirit and scope of the present principles as defined by the claims.

The terminology used herein is for the purpose of describing particular examples only and is not intended to be limiting of the present principles. As used herein, the singular forms “a”, “an” and “the” are intended to include the plural forms as well, unless the context clearly indicates otherwise. It will be further understood that the terms “comprises”, “comprising,” “includes” and/or “including” when used in this specification, specify the presence of stated features, integers, steps, operations, elements, and/or components but do not preclude the presence or addition of one or more other features, integers, steps, operations, elements, components, and/or groups thereof. Moreover, when an element is referred to as being “responsive” or “connected” to another element, it can be directly responsive or connected to the other element, or intervening elements may be present. In contrast, when an element is referred to as being “directly responsive” or “directly connected” to other element, there are no intervening elements present. As used herein the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the present principles.

Although some of the diagrams include arrows on communication paths to show a primary direction of communication, it is to be understood that communication may occur in the opposite direction to the depicted arrows.

Some examples are described with regard to block diagrams and operational flowcharts in which each block represents a circuit element, module, or portion of code which comprises one or more executable instructions for implementing the specified logical function(s). It should also be noted that in other implementations, the function(s) noted in the blocks may occur out of the order noted. For example, two blocks shown in succession may, in fact, be executed substantially concurrently or the blocks may sometimes be executed in the reverse order, depending on the functionality involved.

Reference herein to “in accordance with an example” or “in an example” means that a particular feature, structure, or characteristic described in connection with the example can be included in at least one implementation of the present principles. The appearances of the phrase in accordance with an example” or “in an example” in various places in the specification are not necessarily all referring to the same example, nor are separate or alternative examples necessarily mutually exclusive of other examples.

Reference numerals appearing in the claims are by way of illustration only and shall have no limiting effect on the scope of the claims. While not explicitly described, the present examples and variants may be employed in any combination or sub-combination.

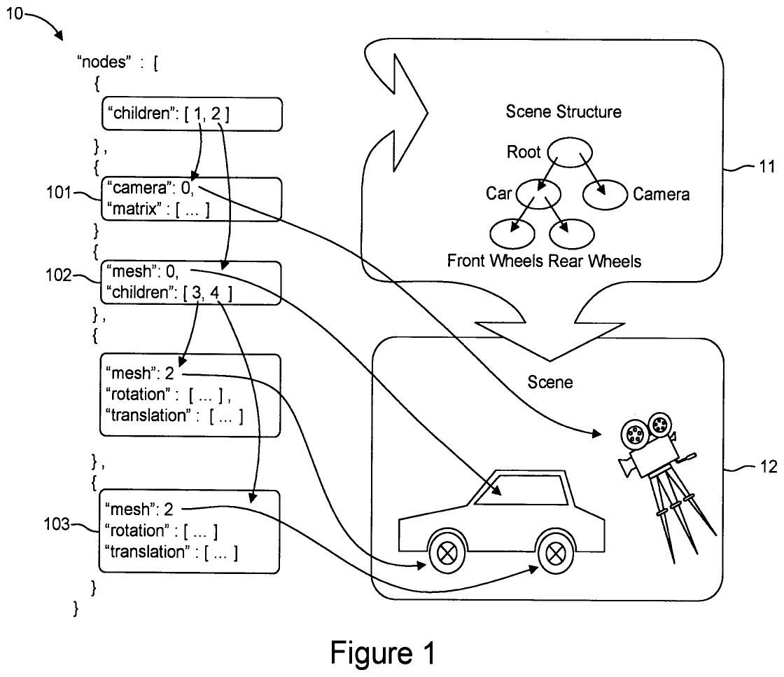

FIG. 1 shows an example graph 10 of an extended reality scene description. In this example, the scene graph may comprise a description of real objects, for example ‘plane horizontal surface’ (that can be a table or a road) and a description of virtual objects 12, for example an animation of a car. Scene description is organized as an array 10 of nodes. A node can be linked to child nodes to form a scene structure 11. A node can carry a description of a real object (e.g. a semantic description) or a description of a virtual object. In the example of FIG. 1, node 101 describes a virtual camera located in the 3D volume of the XR application. Node 102 described a virtual car and comprises an index of a representation of the car, for example an index in an array of 3D meshes. The scene description may comprise numerous arrays comprising descriptions of various aspect of the scene, for example an array containing instructions for several animations, an array containing meshes of several objects or an array comprising material descriptions. Node 103 is a child of node 102 and comprises a description of one wheel of the car. The same way, it comprises an index to the 3D mesh of the wheel. The same 3D mesh may be used for several objects in the 3D scene as the scale, location and orientation of objects are described in the scene nodes. Scene graph 10 also comprises nodes that are a description of the spatial relation between the real objects and the virtual objects.

XR applications are various and may apply to different context and real or virtual environments. For example, in an industrial XR application, a virtual 3D content item (e.g. a piece A of an engine) is displayed when a reference object (piece B of an engine) is detected in the real environment by a camera rigged on a head mounted display device. The 3D content item is positioned in the real-world with a position and a scale defined relatively to the detected reference object. In the same way, actions on virtual objects may be performed when a collision between real or virtual objects is detected, that is a collision between two real objects, two virtual objects or a real object and a virtual object.

For example, in an XR application for interior design, the color of a displayed virtual furniture is changed when the user touches a virtual control object or when the user touches a real table. In another application, some audio file might start playing when two moving displayed virtual objects collide. In another example, an ad jingle file may be played when the user grabs a can of a given soda in the real environment. However, detecting collision (or contacts) between real or virtual objects and rendering realistic reactions of virtual objects requires the use of a physics engine that is expansive in terms of memory and processing resources. So, it is important to have a scene description that accurately describes the different kinds of behaviors linked to collisions in order to optimize the use of the physics engine. Such an XR scene description format is provided herein according to the present principles.

An XR application may also augment a video content rather than a real environment. The video is displayed on a rendering device and virtual objects described in the node tree are overlaid when timed events are detected in the video. In such a context, the node tree comprises only virtual objects descriptions.

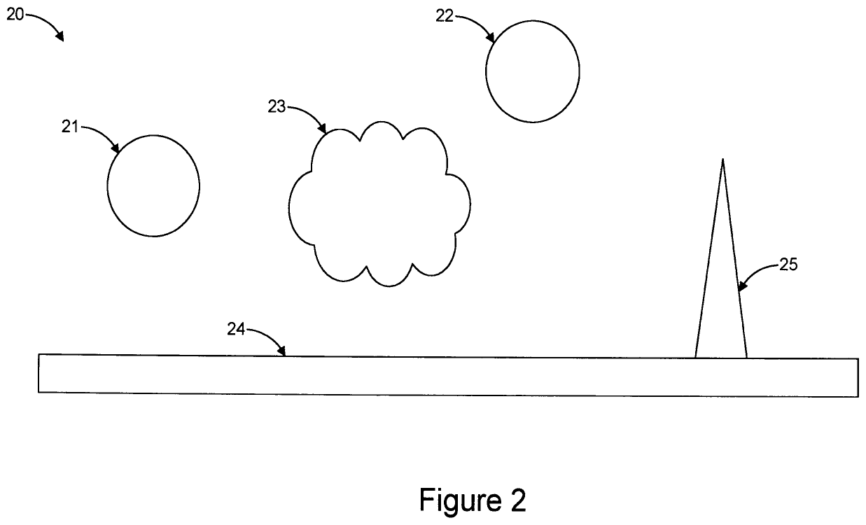

FIG. 2 shows a non-limitative example of an extended reality scene 20 comprising real and virtual objects 21 to 25. An XR scene description may comprise behaviors data at the scene level. A behavior is related to virtual objects on which runtime interactivity is allowed for user specific XR experiences. As every element of the XR scene description, behaviors are time-evolving and are updated thanks to a scene description update mechanism.

A behavior is described at scene level in the scene description and comprises:
triggers defining the conditions to be met for their activation,
a trigger control parameter defining logical operations between the triggers for the application of the actions,
actions to be processed when the triggers are activated according to the trigger control parameter,
an action control parameter defining the order of execution of the actions,
a priority number enabling the selection of the behavior of highest priority in case of competition between several behaviors on the same virtual object at the same time, and
an optional interrupt action that specifies how to terminate the behavior when it is no longer defined in an update of the scene description. For instance, a behavior is no longer defined when a related object does no longer belong to the new scene or when the behavior is no longer relevant for this current media (e.g. audio or video) sequence.

In such a scene description, collisions are handled by collision triggers at the scene level. A collision trigger is activated when a collision is detected between the two objects describes by the two nodes referenced in its description.

In an exemplary scenario for the scene of FIG. 2:
Objects described by nodes 21, 22 and 24 are collidable nodes; So, they have to be managed by the physics simulation engine. They can be referenced by a collision trigger. According to the present principles, an XR scene description identifies this first category of objects so the rendering device can instantiate the physics engine for collision detections and for physics simulation.
Object of node 23 is also a collidable node but behaves as a “ghost” object, that its movements are not managed by the physics simulation engine. Typically, another object (like 21 or 22) can go through the object described by node 23 without physical interaction. It is useful for a scene creator to be able to introduce this kind of objects in a scene. Indeed, object of node 23 requires the physics engine for collision detection only and does not require the use of a physics simulation for itself and for the other objects, saving memory and processing resources of the XR rendering device. According to the present principles, an XR scene description identifies this second category of objects so the rendering device can instantiate the physics engine only for collision detections. A ghost object may be referenced by a collision trigger.
Object of node 25 is a solid object but, the scene is built by the content creators so that this object does not have any collision with another object, in every possible development of the scenario. For example, it can be an object visible but far from the volume of the interaction and no moving object can approach it. It is useful for a scene creator to be able to introduce this kind of objects in a scene. Indeed, object of node 25 does not require the use of the physics engine at all, saving memory and processing resources of the XR rendering device. According to the present principles, an XR scene description identifies this third category of objects so the rendering device can provide them from being managed by the physics engine.

The exemplary scenario of FIG. 2 may comprise the following behaviors. A first behavior comprising a single trigger activated by a collision between objects of nodes 21 and 22. When this single trigger is activated, for example, object of node 25 turns red. A second behavior comprising a single trigger activated by a collision between objects of nodes 21 and 23 (that is the ghost object). When this single trigger is activated, for example, object of node 25 turns green.

According to the present principles, in complement to the scene-level behaviors, a node-level information indicates whether a node is a collidable node. Possible semantics of this information is provided in the following table. In this embodiment, the physics material parameters are provided as a reference to a physics material array as described upper. In another embodiment, the physics material parameters may be described in the nodes.

| Name | Type | Default | Description |
|---|---|---|---|
| static | Boolean | false | Indicates if the object is able to move or is |
| | | | always static. |
| colliderMesh | number | | Index of the mesh in the scene meshes array |
| | | | used as collider geometry to determine a |
| | | | collision event. |
| allowOverlap | Boolean | false | Indicates if the object shall be considered by |
| | | | the physics simulation. |
| If (allowOverlap == | | | |
| false) | | | |
| { | | | |
| useGravity | Boolean | true | Indicates if the gravity affects the object |
| mass | number | 1 | Mass of the object in kilogram. |
| physicsMaterial | number | | Index of the material in the scene materials |
| | | | array defining the object physics material |
| | | | properties (bounciness, roughness/friction) |
| | | | used by the physics simulation to compute |
| | | | collision. |
| } | | | |

The collider mesh is a mesh (that may be a simplified mesh) used for the collision detection. A box, a sphere or a capsule may be used, for example, to accelerate collision detections. Fields “useGravity” and “mass” are physics body parameters. Advanced parameters may be envisaged to control further the physics simulation such as a “freeze rotation” Boolean which indicates if the physics simulation shall modify the object rotation, a “maximum angular velocity” value which limits the angular velocity in radians per second and/or a “maximum depenetration velocity” value which limits the object velocity when moving out of colliding state.

The physics material (described in an array for physics material items or directly at the node level) may comprise the following parameters:

| Name | Type | Default | Description |
|---|---|---|---|
| bounciness | number | 0.0 | Provides the amount that an object bounces in |
| | | | response to a collision. The typical range is [0.0 1.0], |
| | | | where 0.0 represents completely not bouncy and 1.0 |
| | | | represents the maximum bounciest. |
| roughness | number | 0.5 | Provides the roughness of an object which affects |
| | | | how much the object moves in response to a |
| | | | collision. The typical range is [0.0 1.0]. |

The parameters of a given node for collision detections according to the present principles apply to the child node of this given node. So, parents and children of the given node do not comprise the fields listed in the first table upper.

In the exemplary scenario of FIG. 2, nodes 21, 22, 23 and 24 comprise the information according to the present principles and listed in the first table, making them collidable nodes. So, they can be referenced by the two collision triggers. Each of these nodes has its specific physics parameters defined according to the present principles. For instance, node 23 has a true allowOverlap Boolean which allows its overlapping by any other object to allow a “ghost” behavior. Node 24 has a false useGravity Boolean to allow a ground plane behavior in physics simulation (the ground does not fall). A gravity acceleration vector, which defines the direction and the force of the gravity, shall be defined for the physics simulation. The gravity acceleration vector is expressed in meter per second squared. The default value may be the Earth gravity (0.0, −9.81, 0.0) if y is the vertical axis. In a first embodiment, the gravity vector is defined at scene level. In another embodiment, a gravity vector is defined at the node level (making possible scenarios in which different object do not fall at the same speed, for example to simulate frictions at low processing resources cost). According to the present principles, having the collision parameters at the scene level allows to define additional parameters, such as default values of some physics body parameters.

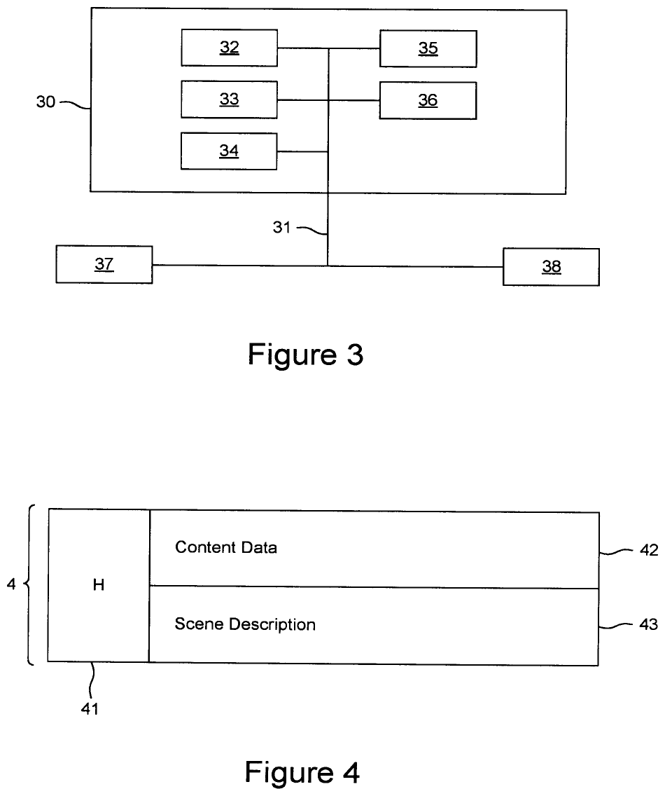

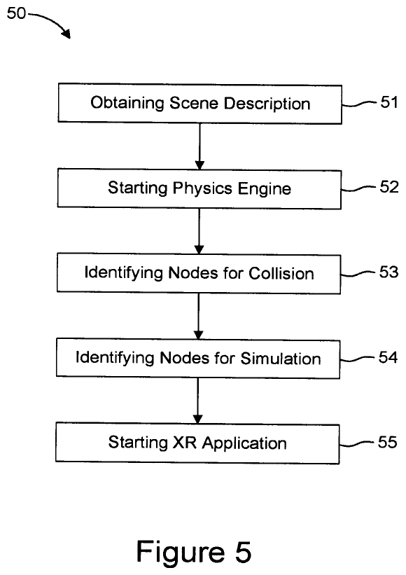

FIG. 3 shows an example architecture of an XR processing engine 30 which may be configured to implement a method described in relation with FIG. 5. A device according to the architecture of FIG. 3 is linked with other devices via their bus 31 and/or via I/O interface 36.

Device 30 comprises following elements that are linked together by a data and address bus 31:
a microprocessor 32 (or CPU), which is, for example, a DSP (or Digital Signal Processor);
a ROM (or Read Only Memory) 33;
a RAM (or Random Access Memory) 34;
a storage interface 35;
an I/O interface 36 for reception of data to transmit, from an application; and
a power supply (not represented in FIG. 3), e.g. a battery.

In accordance with an example, the power supply is external to the device. In each of mentioned memory, the word «register» used in the specification may correspond to area of small capacity (some bits) or to very large area (e.g. a whole program or large amount of received or decoded data). The ROM 33 comprises at least a program and parameters. The ROM 33 may store algorithms and instructions to perform techniques in accordance with present principles. When switched on, the CPU 32 uploads the program in the RAM and executes the corresponding instructions.

The RAM 34 comprises, in a register, the program executed by the CPU 32 and uploaded after switch-on of the device 30, input data in a register, intermediate data in different states of the method in a register, and other variables used for the execution of the method in a register.

The implementations described herein may be implemented in, for example, a method or a process, an apparatus, a computer program product, a data stream, or a signal. Even if only discussed in the context of a single form of implementation (for example, discussed only as a method or a device), the implementation of features discussed may also be implemented in other forms (for example a program). An apparatus may be implemented in, for example, appropriate hardware, software, and firmware. The methods may be implemented in, for example, an apparatus such as, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Device 30 is linked, for example via bus 31 to a set of sensors 37 and to a set of rendering devices 38. Sensors 37 may be, for example, cameras, microphones, temperature sensors, Inertial Measurement Units, GPS, hygrometry sensors, IR or UV light sensors or wind sensors. Rendering devices 38 may be, for example, displays, speakers, vibrators, heat, fan, etc.

In accordance with examples, the device 30 is configured to implement a method according to the present principles described in relation to FIG. 5, and belongs to a set comprising:
a mobile device;
a communication device;
a game device;
a tablet (or tablet computer);
a laptop;
a still picture camera;
a video camera.

FIG. 4 shows an example of an embodiment of the syntax of a data stream encoding an extended reality scene description according to the present principles. FIG. 4 shows an example structure 4 of an XR scene description. The structure consists in a container which organizes the stream in independent elements of syntax. The structure may comprise a header part 41 which is a set of data common to every syntax element of the stream. For example, the header part comprises some of metadata about syntax elements, describing the nature and the role of each of them. The structure also comprises a payload comprising an element of syntax 42 and an element of syntax 43. Syntax element 42 comprises data representative of the media content items describes in the nodes of the scene graph related to virtual elements. Images, meshes and other raw data may have been compressed according to a compression method. Element of syntax 43 is a part of the payload of the data stream and comprises data encoding the scene description as described according to the present principles.

FIG. 5 illustrates a method 50 for initiating an extended reality application comprising collision events according to the present principles. In a step 51, a scene description is obtained. According to the present principles, the scene description comprises behavior information involving collision triggers at scene level. According to the present principles, the nodes of the scene graph of the scene description may comprise collision information as described in the first table of the present document in relation to FIG. 2. The scene description may comprise physics parameters at the scene level (e.g. gravity parameters). The physics engine of the application is started and initialized with these physics parameters at a step 52. At step 53, the scene graph of the scene description is parsed to distinguish three categories of nodes. Nodes that do not comprise collision information according to the present principles are not linked to the physics engine, that is the physics engine does not manage their collision and the simulation of their physics properties. Nodes that comprise collision information according to the present principles are linked to the physics engine for the management of collisions at step 53. The physics engine is initialized for each of these nodes with a Boolean value indicating if the object is able to move or is always static and with a mesh (for example stored in a mesh array and referenced by an index in the collision information of the node) that is used to detect collisions. Additional parameters comprised in the collision information of a given node may be used to initialized to collision detection feature of the physics engine. At step 54, nodes of the scene graph comprising a collision information having a boolean value (herein called “allowOverlap”) indicating whether the object shall be considered by the physics simulation set to true are linked to the physics engine for the physics simulation feature of the physics engine. For such a node, the physics engine is initialized with physics body parameters comprised in the collision information of the node (e.g. a “useGravity” Boolean value, a mass or velocity parameters) and with a material description (which may be stored in a material table or described in the node). At step 55, when the physics engine is initialized with only relevant object properties, the XR application is started.

A syntax example of the scene description of FIG. 2 is provided below as an extension to the MPEG-I Scene Description.

At the scene level, a single interactivity behavior is defined and is composed of one collision trigger between the first and second node, an activate action enabling the third node. A moon gravity acceleration vector (0, −1.625, 0) is defined. At the node level, the first node is a collidable dynamic (i.e. static=false) object using physics simulation with related physics material corresponding to the first material in the materials array. The second node is a collidable static object with no physics simulation (i.e. allowOverlap=true). The third node is a non-collidable object which is ignored by the physics engine. At the material level, the first material with physics parameters of bounciness (0.8) and roughness (0.1).

```
{
  ″extensionUsed″[
    ″MPEG_scene_interactivity″,
    ″MPEG_scene_collision_handling″
    ″MPEG_node_collision_handling″
    ″MPEG_material_collision_handling″
  ],
  ″scene″: 0,
  ″scenes″: [
    {
      ″extensions″: {
        ″MPEG_scene_interactivity″: {
          ″triggers:″ [
            {
            ″type″: COOLIDER,
            ″ nodes″″[0,1]
            },
          ],
          ″actions:″ [
            {
            ″ type″: ACTIVATE,
            ″ activationStatus″ : ENABLED
            ″ nodes ″[2]
            }
          ],
          ″behaviors:″ [
            {
            ″triggers″:[0],
            ″actions″:[0]
            }
          ]
        },
        ″ MPEG_scene_collision_handling ″: {
            ″gravityAccelerationVector″:[0, −1.625, 0]
        },
        ″name″: ″Scene″,
        ″nodes″: [
          0
        ]
  ],
  ″nodes″: [
    {
        ″extension″: {
          ″ MPEG_node_collision_handling ″: {
              ″static″: false,
              ″colliderMesh″: 0,
              ″allowOverlap″: false,
              ″mass″: 5.2,
              ″physicsMaterial″: 0
        }
        ″name″: ″Node0″,
        ″mesh″: 0,
        ″matrix″: [1,0,0,0
                0,0,−1,0,
                0,1,0,0,
                −16.2,−5.5,44.8,1
                ]
    },
    {
        ″extension″: {
          ″ MPEG_node_collision_handling ″: {
              ″static″: true
              ″colliderMesh″: 1,
              ″allowOverlap″:true
        }
        ″name″: ″Node1″,
        ″mesh″: 1,
        ″matrix″: [1,0,0,0
                0,0,−1,0,
                0,1,0,0,
                15.5,−18,1
                ]
    },
    {
        ″name″: ″Node2″,
        ″mesh″: 2,
        ″matrix″: [1,0,0,0
                0,0,−1,0,
                0,1,0,0,
                −5,7,−1,1
                ]
    },
    ...
  ]
  ″materials″: [
    {
    ″extensions″: {
          ″ MPEG_material_collision_handling ″: {
              ″bounciness″: 0.8,
              ″roughness″:0.1
        }
    ...
    },
    ...
  ]
  ...
}
```

The implementations described herein may be implemented in, for example, a method or a process, an apparatus, a computer program product, a data stream, or a signal. Even if only discussed in the context of a single form of implementation (for example, discussed only as a method or a device), the implementation of features discussed may also be implemented in other forms (for example a program). An apparatus may be implemented in, for example, appropriate hardware, software, and firmware. The methods may be implemented in, for example, an apparatus such as, for example, a processor, which refers to processing devices in general, including, for example, a computer, a microprocessor, an integrated circuit, or a programmable logic device. Processors also include communication devices, such as, for example, Smartphones, tablets, computers, mobile phones, portable/personal digital assistants (“PDAs”), and other devices that facilitate communication of information between end-users.

Implementations of the various processes and features described herein may be embodied in a variety of different equipment or applications, particularly, for example, equipment or applications associated with data encoding, data decoding, view generation, texture processing, and other processing of images and related texture information and/or depth information. Examples of such equipment include an encoder, a decoder, a post-processor processing output from a decoder, a pre-processor providing input to an encoder, a video coder, a video decoder, a video codec, a web server, a set-top box, a laptop, a personal computer, a cell phone, a PDA, and other communication devices. As should be clear, the equipment may be mobile and even installed in a mobile vehicle.

Additionally, the methods may be implemented by instructions being performed by a processor, and such instructions (and/or data values produced by an implementation) may be stored on a processor-readable medium such as, for example, an integrated circuit, a software carrier or other storage device such as, for example, a hard disk, a compact diskette (“CD”), an optical disc (such as, for example, a DVD, often referred to as a digital versatile disc or a digital video disc), a random access memory (“RAM”), or a read-only memory (“ROM”). The instructions may form an application program tangibly embodied on a processor-readable medium. Instructions may be, for example, in hardware, firmware, software, or a combination. Instructions may be found in, for example, an operating system, a separate application, or a combination of the two. A processor may be characterized, therefore, as, for example, both a device configured to carry out a process and a device that includes a processor-readable medium (such as a storage device) having instructions for carrying out a process. Further, a processor-readable medium may store, in addition to or in lieu of instructions, data values produced by an implementation.

As will be evident to one of skill in the art, implementations may produce a variety of signals formatted to carry information that may be, for example, stored or transmitted. The information may include, for example, instructions for performing a method, or data produced by one of the described implementations. For example, a signal may be formatted to carry as data the rules for writing or reading the syntax of a described embodiment, or to carry as data the actual syntax-values written by a described embodiment. Such a signal may be formatted, for example, as an electromagnetic wave (for example, using a radio frequency portion of spectrum) or as a baseband signal. The formatting may include, for example, encoding a data stream and modulating a carrier with the encoded data stream. The information that the signal carries may be, for example, analog or digital information. The signal may be transmitted over a variety of different wired or wireless links, as is known. The signal may be stored on a processor-readable medium.

A number of implementations have been described. Nevertheless, it will be understood that various modifications may be made. For example, elements of different implementations may be combined, supplemented, modified, or removed to produce other implementations. Additionally, one of ordinary skill will understand that other structures and processes may be substituted for those disclosed and the resulting implementations will perform at least substantially the same function(s), in at least substantially the same way(s), to achieve at least substantially the same result(s) as the implementations disclosed. Accordingly, these and other implementations are contemplated by this application.

1. A method of initiating an extended reality application using a physics engine, the method comprising:
obtaining a description of an extended reality scene comprising a scene graph, wherein at least two nodes of the scene graph comprise collision information, and wherein the collision information comprises:
a first Boolean value indicating whether an object described in the node is static, a mesh information and a second Boolean value indicating whether physics of the object described in the node is simulated; and
on condition that the second Boolean value is true, physics body parameters and material information;
for nodes of the scene graph comprising collision information, initializing the physics engine for collision detection with the first Boolean value and the mesh information; and, on condition that the second Boolean value is true, initializing the physics engine for physics simulation with the physics body parameters and the material information; and
initiating the extended reality application.

2. The method of claim 1, wherein the mesh information is an index in a mesh table of the description.

3. The method of claim 1, wherein the material information is an index in a material table of the description.

4. The method of claim 1, wherein the material information is described in the collision information.

5. A device initiating an extended reality application using a physics engine, wherein the device comprises a memory and a processor configured for:
obtaining a description of an extended reality scene comprising a scene graph, wherein at least two nodes of the scene graph comprise collision information, and wherein the collision information comprises:
a first Boolean value indicating whether an object described in the node is static, a mesh information and a second Boolean value indicating whether physics of the object described in the node is simulated; and
on condition that the second Boolean value is true, physics body parameters and material information;
for nodes of the scene graph comprising a collision information, initializing the physics engine for collision detection with the first Boolean value and the mesh information; and, on condition that the second Boolean value is true, initializing the physics engine for physics simulation with the physics body parameters and the material information; and
initiating the extended reality application.

6. The device of claim 5, wherein the mesh information is an index in a mesh table of the description.

7. The device of claim 5, wherein the material information is an index in a material table of the description.

8. The device of claim 5, wherein the material information is described in the collision information.

9. A non-transitory computer-readable medium carrying data representative of a description of an extended reality scene, wherein the description comprises:
a scene graph;
at least two nodes of the scene graph comprising collision information, wherein the collision information comprises:
a first Boolean value indicating whether an object described in the node is static, a mesh information and a second Boolean value indicating whether physics of the object described in the node is simulated; and
on condition that the second Boolean value is true, physics body parameters and material information.

10. The non-transitory computer-readable medium of claim 9, wherein the mesh information is an index in a mesh table of the description.

11. The non-transitory computer-readable medium of claim 9, wherein the material information is an index in a material table of the description.

12. The non-transitory computer-readable medium of claim 9, wherein the material information is described in the collision information.
